(19) United States
(12) Patent Application Publication
(10) Pub. No.: US 2009/0160053 A1
(43) Pub. Date: Jun. 25, 2009

(54) METHOD OF MANUFACTURING A SEMICONDUCOTOR DEVICE

(75) Inventors: Thorsten Meyer, Regensburg (DE); Gerald Ofner, Schierling (DE); Rainer Steiner, Regensburg (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AG, Neubiberg (DE)

(21) Appl. No.: 11/959,995

(22) Filed: Dec. 19, 2007

(51) Int. Cl. H01L 21/60; H01L 23/52

(52) U.S. Cl. 257/738; 438/110; 257/E23.141; 257/E21.506

(57) ABSTRACT

A method of manufacturing a semiconductor device is disclosed. One embodiment provides a carrier. Semiconductor chips are placed over the carrier. The semiconductor chips include contact elements. A polymer material is applied over the semiconductor chips and the carrier. The polymer material is removed until the contact elements are exposed. The carrier is removed from the semiconductor chips.

### BACKGROUND

This invention relates to a semiconductor device and a method of manufacturing a semiconductor device.

Wafer level packaging is gaining interest throughout the semiconductor industry due to advantages in cost and performance. When standard wafer level package technologies are used, all technology processes are performed at the wafer level. Since standard wafer level packages are fan-in solutions, only a limited number of contact pads under the semiconductor chip is possible. Thus, for the placement of a large number of contact pads the semiconductor chip may be designed bigger or an additional material may be placed as a space holder around the die to bear the wiring that allows fan-out redistribution.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIGS. 1A to 1F schematically illustrate a method to produce devices 100 as an exemplary embodiment.

FIGS. 2A to 2R schematically illustrate a method to produce devices 200 as a further exemplary embodiment.

FIG. 3 schematically illustrates a device 300 as a further exemplary embodiment.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

Devices with semiconductor chips embedded in a polymer material are described below. The semiconductor chips may be of extremely different types, may be manufactured by different technologies and may include for example integrated electrical or electro-optical circuits or passives. The integrated circuits may, for example, be designed as logic integrated circuits, analog integrated circuits, mixed signal integrated circuits, power integrated circuits, memory circuits or integrated passives. Furthermore, the semiconductor chips may be configured as MEMS (micro-electro mechanical systems) and may include micro-mechanical structures, such as bridges, membranes or tongue structures. The semiconductor chips may be configured as sensors or actuators, for example pressure sensors, acceleration sensors, rotation sensors, microphones etc. The semiconductor chips may be configured as antennas and/or discrete passives and/or chip stacks. The semiconductor chips may also include antennas and/or discrete passives. Semiconductor chips in which such functional elements are embedded generally contain electronic circuits which serve for driving the functional elements or further process signals generated by the functional elements. The semiconductor chips need not be manufactured from specific semiconductor material and, furthermore, may contain inorganic and/or organic materials that are not semiconductors, such as for example discrete passives, antennas, insulators, plastics or metals. Moreover, the semiconductor chips may be packaged or unpackaged.

The semiconductor chips have contact pads which allow electrical contact to be made with the semiconductor chips. The contact pads may be composed of any desired electrically conductive material, for example of a metal, such as aluminum, nickel, palladium, gold or copper, a metal alloy, a metal stack or an electrically conductive organic material. The contact pads may be situated on the active main surfaces of the semiconductor chips or on other surfaces of the semiconductor chips.

Contact elements may be placed on a surface of the semiconductor chips such that they protrude from the surface. The contact elements may, for example, be produced by stud bumping or electro-less plating. The contact elements are manufactured from an electrically conductive material.

The devices described below may include external connection elements. The external connection elements are accessible from outside the device and allow electrical contact to be made with the semiconductor chips from outside the device. The external connection elements may, for example, be solder balls or solder bumps.

The semiconductor chips or at least parts of the semiconductor chips may be covered with a polymer material. The polymer material may be any appropriate laminate (prepreg), duroplastic, thermoplastic or thermosetting material and may contain filler materials. After its deposition the polymer material may be only partly hardened and may be completely hardened after a heat treatment. Various techniques may be employed to cover the semiconductor chips with the polymer material, for example lamination, compression molding or injection molding.

The polymer material may be used to produce fan-out type packages. In a fan-out type package at least some of the external connection elements and/or conductor tracks connecting the semiconductor chip to the external connection elements are located laterally outside of the outline of the semiconductor chip or do at least intersect the outline of the semiconductor chip. Thus, in fan-out type packages, a peripherally outer part of the package of the semiconductor chip is typically (additionally) used for electrically bonding the package to external applications, such as application boards etc. This outer part of the package encompassing the semiconductor chip effectively enlarges the contact area of the package in relation to the footprint of the semiconductor chip, thus leading to relaxed constraints in view of package pad size and pitch with regard to later processing, e.g., second level assembly.

One or more electrically conductive layers may be applied to the polymer material, for example to produce a redistribution layer. The electrically conductive layers may be used as wiring layers to make electrical contact with the semiconductor chips from outside the devices or to make electrical contact with other semiconductor chips and/or components contained in the devices. The electrically conductive layers may be manufactured with any desired geometric shape and any desired material composition. The electrically conductive layers may, for example, be composed of conductor tracks, but may also be in the form of a layer covering an area. Any desired electrically conductive materials, such as metals, for example aluminum, nickel, palladium, silver, tin, gold or copper, metal alloys, metal stacks or organic conductors, may be used as the material. The electrically conductive layers need not be homogenous or manufactured from just one material, that is to say various compositions and concentrations of the materials contained in the electrically conductive layers are possible. Furthermore, the electrically conductive layers may be arranged above or below or between electrically insulating layers.

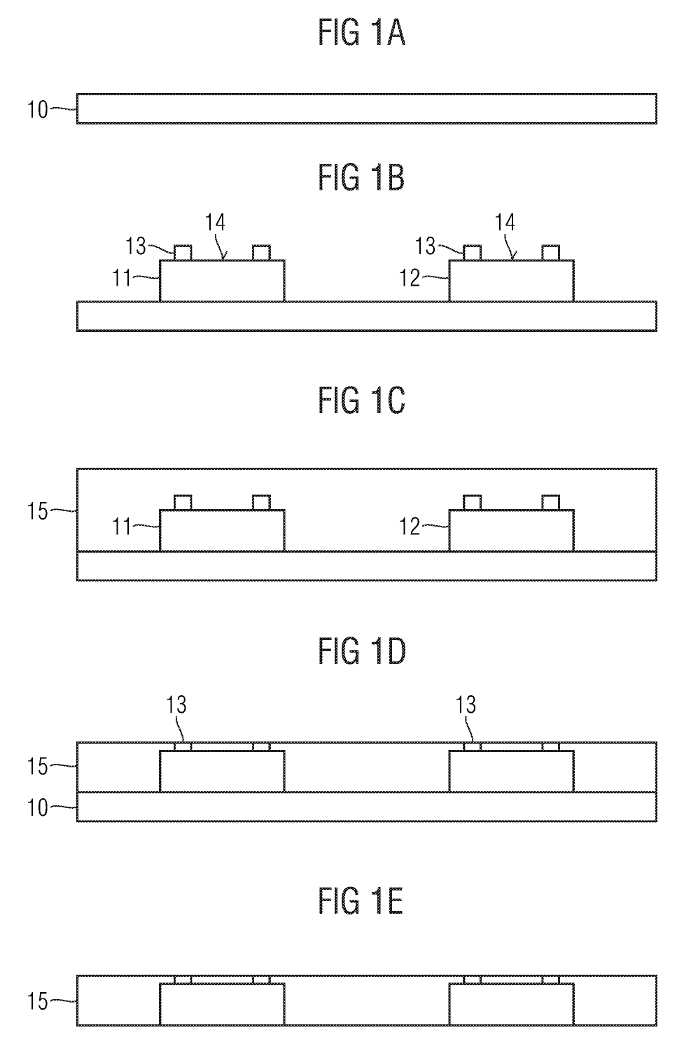

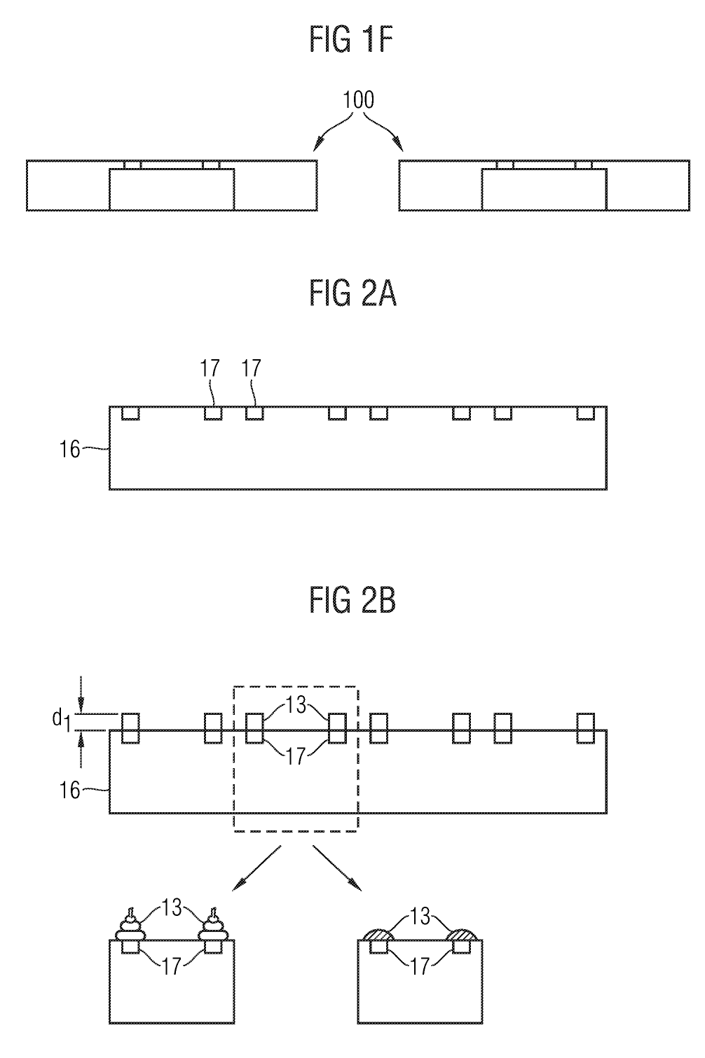

FIGS. 1A to 1F schematically illustrate a method for production of devices 100. Cross sections of the devices 100 obtained by the method are illustrated in FIG. 1F. Firstly, a carrier 10 is provided (see FIG. 1A). A plurality of semiconductor chips, for example an array of semiconductor chips, is placed on the carrier 10. In FIG. 1B semiconductor chips 11 and 12 of the plurality of the semiconductor chips are illustrated. The plurality of semiconductor chips may contain further semiconductor chips which are placed on the carrier 10 and which are not illustrated in FIG. 1B. The semiconductor chips 11 and 12 have contact elements 13 protruding from their first surfaces 14 by at least 1, 2, 3, 4 or 5 μm. When the semiconductor chips 11 and 12 are placed on the carrier 10, the first surfaces 14 face away from the carrier 10.

The carrier 10 and the semiconductor chips 11 and 12 are covered with a polymer material 15 (see FIG. 1C). The polymer material 15 is then partly removed, for example by grinding, until the contact elements 13 protruding from the first surfaces 14 are opened (see FIG. 1D). Optionally, the semiconductor chips 11 and 12 together with the polymer material 15 may be released from the carrier 10 (see FIG. 1E). The semiconductor chips 11 and 12 may be singulated by dividing the polymer material 15 (see FIG. 1F). In case the semiconductor chips 11 and 12 are not released from the carrier 10, the carrier 10 is also divided during singulation and is part of the devices 100.

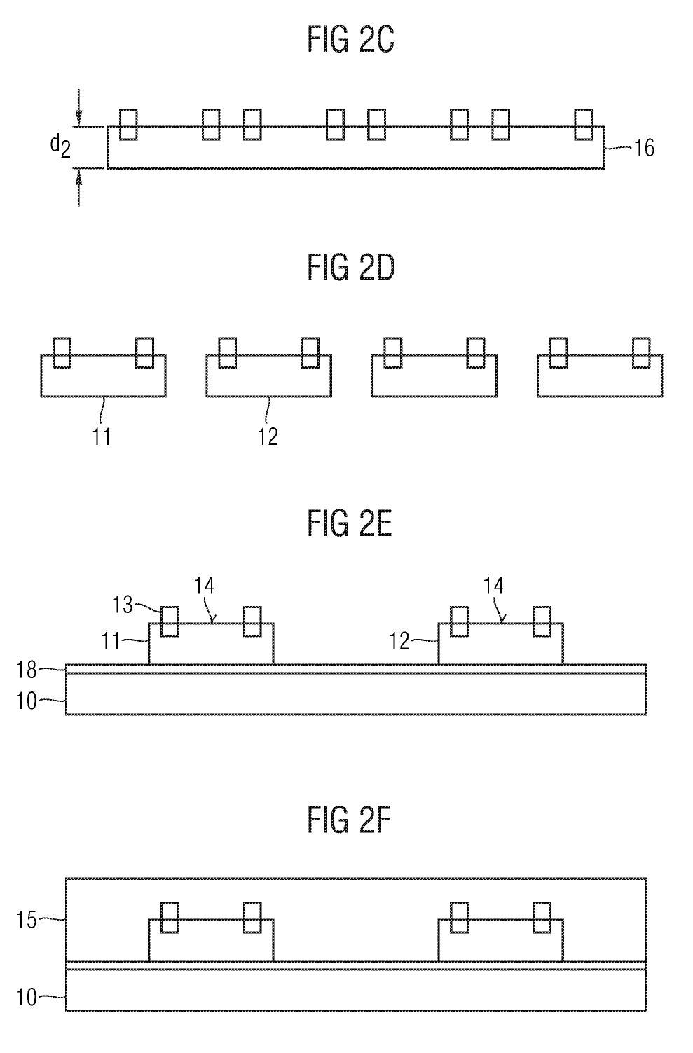

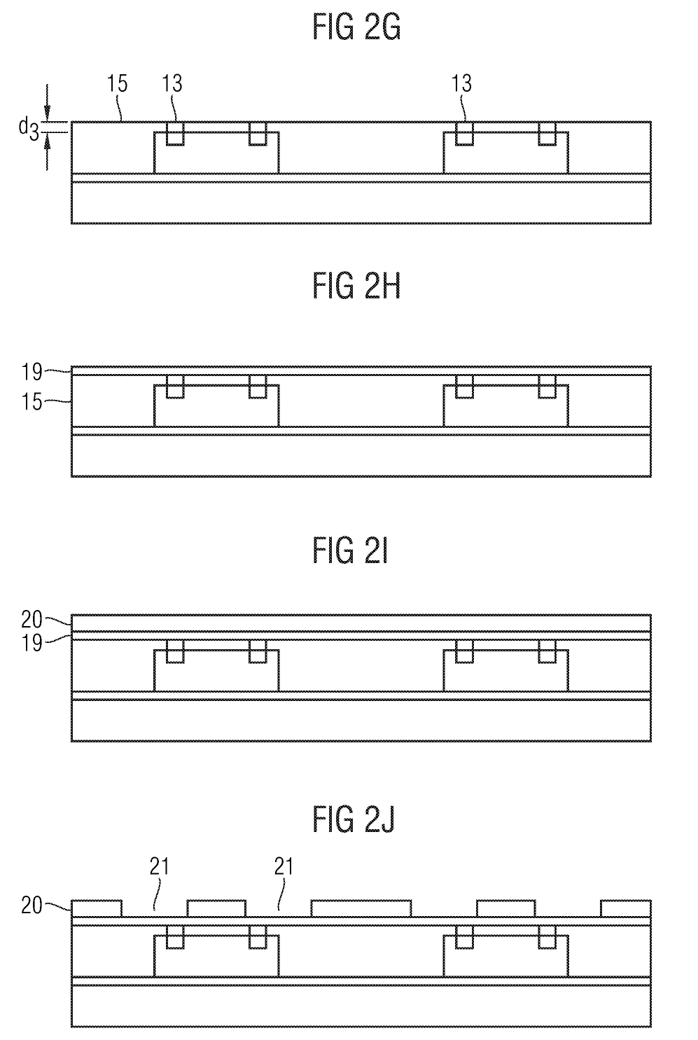

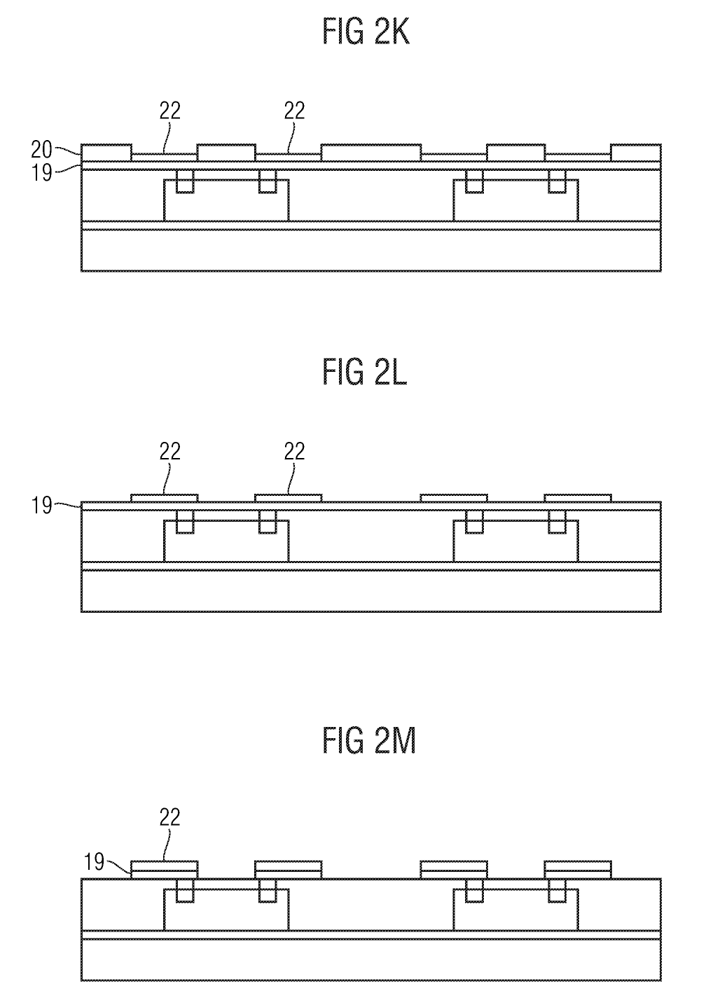

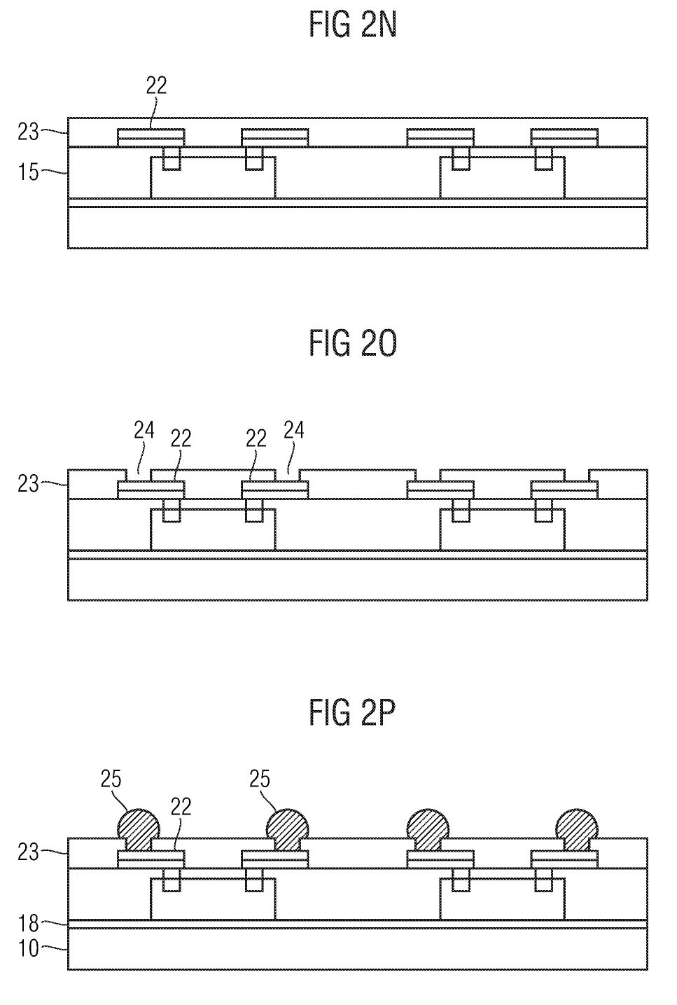

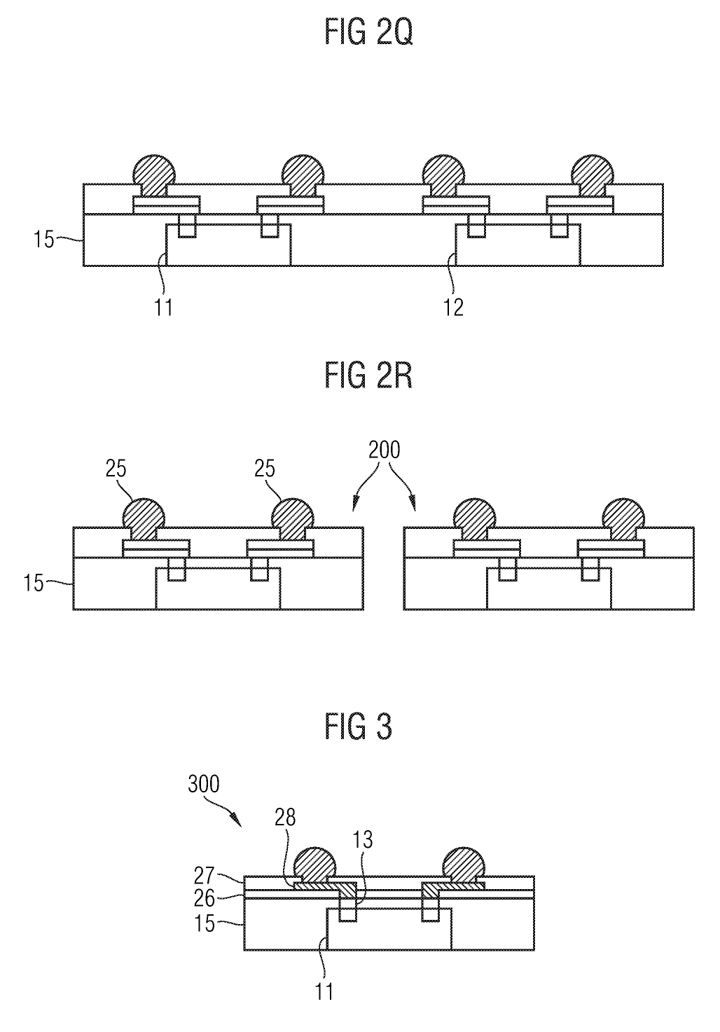

FIGS. 2A to 2R schematically illustrate a method for production of devices 200, cross sections of which are illustrated in FIG. 2R. The method illustrated in FIGS. 2A to 2R is a development of the method illustrated in FIGS. 1A to 1F. The details of the production method that are described below can therefore be likewise applied to the method of FIGS. 1A to 1F.

The semiconductor chips 11 and 12 as well as all other semiconductor chips described herein may be fabricated on a wafer made of semiconductor material. Such a semiconductor wafer 16 is illustrated in FIG. 2A. The semiconductor wafer 16 has contact pads 17 located on its upper surface, which is for example its active main surface. The integrated circuits embedded in the semiconductor wafer 16 can be electrically accessed via the contact pads 17. The contact pads 17 may be made of a metal, for example aluminum or copper.

The contact elements 13 are placed on the contact pads 17 (see FIG. 2B). The contact elements 13 may be composed of any desired electrically conductive material, for example of a metal, a metal alloy, a metal stack or an electrically conductive organic material. The contact elements 13 may have a height d₁ in the range from 1 to 20 μm protruding from the upper surface of the semiconductor wafer 16, but they may be even larger. Any appropriate method may be utilized to produce the contact elements 13. By way of example, stud bumping (left) and electro-less plating (right) are illustrated in the lower part of FIG. 2B.

Stud bumps 13 are placed on the contact pads 17 through a modification of the “ball bonding” process used in conventional wire bonding. In ball bonding, the tip of the bond wire is melted to form a sphere. The wire bonding tool presses this sphere against the contact pad of the semiconductor chip to be connected, applying mechanical force, heat and/or ultrasonic energy to create a metallic connection. The wire bonding tool next extends the wire to the contact pad on the board, substrate or leadframe and makes a “stitch” bond to that pad, finishing by breaking off the bond wire to begin another cycle. For stud bumping, the first ball bond is made on a contact pad 17 of the semiconductor wafer 16 as described, but the wire is then broken close above the ball (see down left in FIG. 2B). The resulting ball or “stud bump” 13 remaining on the contact pad 17 provides a permanent, reliable connection to the underlying electrically conductive material of the contact pad 17.

In one embodiment, instead of stud bumping, an electrochemical deposition may be utilized to produce the contact elements 13 (see down right in FIG. 2B). For that, a metal layer, for example copper, may be electro-less deposited on the contact pads 17 from a solution. Subsequently other metals, such as nickel and gold, may be electro-less deposited onto the copper layer. Furthermore, other deposition methods, such as sputtering and/or galvanic deposition for example, may also be employed. In the latter cases, however, structuring steps may be necessary.

The semiconductor wafer 16 may be thinned, for example by grinding its backside, down to a thickness d₂ in the range from 30 to 200 μm, in one embodiment in the range from 50 to 100 μm and in one embodiment around 75 μm (see FIG. 2C). The integrated circuits embedded in the semiconductor wafer 16 may be tested, and the semiconductor wafer 16 is diced thereby separating the individual semiconductor chips 11 and 12 as well as further semiconductor chips (see FIG. 2D).

As illustrated in FIG. 2E, the semiconductor chips 11 and 12 as well as possibly further semiconductor chips are placed over the carrier 10. The semiconductor chips may be arranged in an array. The carrier 10 may be a plate made of a rigid material, for example a metal, such as nickel, steel or stainless steel, laminate, film or a material stack. The carrier 10 has a flat surface on which the semiconductor chips 11 and 12 are placed. The shape of the carrier 10 is not limited to any geometric shape, for example the carrier 10 may be round or square-shaped. The carrier 10 may have any appropriate size, for example the diameter or side length of the carrier 10 may be around 200 or 300 mm. Furthermore, any suitable array of semiconductor chips may be placed on the carrier 10 (only two of the semiconductor chips are illustrated in FIG. 2E).

The semiconductor chips 11 and 12 are relocated on the carrier 10 in larger spacing as they have been in the wafer bond. The semiconductor chips 11 and 12 may have been manufactured on the same semiconductor wafer 16 as described above, but may have been manufactured on different wafers. Furthermore, the semiconductor chips 11 and 12 may be physically identical, but may also contain different integrated circuits and/or represent other components. The semiconductor chips 11 and 12 have active main surfaces 14 and are arranged over the carrier 10 with their active main surfaces 14 facing away from the carrier 10.

Before the semiconductor chips 11 and 12 are placed over the carrier 10, an adhesive tape 18, for example a double sided sticky tape, may be laminated onto the carrier 10. The semiconductor chips 11 and 12 can be fixed on the adhesive tape 18. For attaching the semiconductor chips 11 and 12 to the carrier 10, other kinds of attaching materials may be used.

After the semiconductor chips 11 and 12 have been mounted on the carrier 10, they are encapsulated by a polymer material 15 (see FIG. 2F). The polymer material 15 may be an electrically insulating foil or sheet, which is laminated on top of the semiconductor chips 11 and 12 as well as the carrier 10. Heat and pressure may be applied for a time suitable to attach the polymer foil or sheet 15 to the underlying structure. The gaps between the semiconductor chips 11 and 12 are also filled with the polymer material 15. The polymer material 15 may, for example, be a prepreg (short for preimpregnated fibers) that is a combination of a fiber mat, for example glass or carbon fibers, and a resin, for example a duroplastic material. Prepreg materials are usually used to manufacture PCBs (printed circuit boards). Well known prepreg materials that are used in PCB industry and that can be used here as the polymer material 15 are: FR-2, FR-3, FR-4, FR-5, FR-6, G-10, CEM-1, CEM-2, CEM-3, CEM-4 and CEM-5. Prepreg materials are bi-stage materials, which are flexible when applied over the semiconductor chips 11 and 12 and hardened during a heat-treatment. For the lamination of the prepreg the same or similar processes can be used as in PCB manufacturing.

The layer 15 of polymer material is then thinned (see FIG. 2G) by mechanically removing the polymer material from the upper surface of the layer 15. Grinding machines may be used that are similar or identical to the machines used for semiconductor wafer grinding. Milling or polishing, such as chemical mechanical polishing, may be used to reduce the thickness of the layer 15 of polymer material.

Thinning is carried out until the contact elements 13 are exposed. It is also possible that the heights of the contact elements 13 are reduced when thinning the layer 15 of polymer material. At the end, the contact elements 13 as well as the layer 15 of polymer material deposited on top of the semiconductor chips 11 and 12 may have a height d₃ of less than 20 μm, in one embodiment less than 10 or 5 μm. As a result of the thinning, the surface of the layer 15 of polymer material facing away from carrier 10 is flush with the top surfaces of the contact elements 13. The term “flush” is here not meant mathematically and may include micro-steps in the range up to several micrometers. Thus, the upper surfaces of the layer 15 of polymer material and the contact elements 13 form a common planar surface on which a redistribution layer can be applied.

One possibility to produce the redistribution layer is to use a standard PCB industry process flow. As illustrated in FIG. 2H, a thin seed layer 19 of an electrically conductive material, for example copper, is deposited onto the upper surface of the layer 15 and the contact elements 13. The deposition of the seed layer 19 may be carried out by electro-less deposition from a solution or by lamination of a foil or sheet.

On top of the seed layer 19, a dry film 20 may be laminated, which is photostructurable (see FIG. 2I). Recesses 21 are formed in the dry film 20 by exposure to light having a suitable wave-length and subsequent development (see FIG. 2J). The portion of the seed layer 19 exposed by the recesses 21 may be reinforced by galvanic deposition of a further electrically conductive layer 22 (see FIG. 2K). During the galvanic deposition the seed layer 19 is employed as an electrode. Copper or other metals or metal alloys may be plated onto the seed layer 19 in the unmasked areas 21 and to any desired height, which is usually greater than 5 μm. Appropriate surface platings may then be applied.

After the plating the dry film 20 is stripped away (see FIG. 2L) and a brief etching process removes the now exposed original seed layer 19, which has not been covered with the electrically conductive layer 22, thereby creating separated conductor tracks on the layer 15 (see FIG. 2M).

A solder resist layer 23 which is photostructurable may be printed on top of the layers 15 and 22 (see FIG. 2N). By exposure to light having a suitable wave-length and subsequent development, recesses 24 are formed in the solder resist layer 23 (see FIG. 20). The recesses 24 are formed over the electrically conductive layer 22 at appropriate locations. The solder resist layer 23 prevents solder from bridging between the conductor tracks and creating short circuits. The solder resist layer 23 also provides protection from the environment.

Solder deposits 25 may be placed onto the surfaces of the electrically conductive layer 22 exposed from the solder resist layer 23 (see FIG. 2P). The solder deposits 25 may be applied to the redistribution layer by “ball placement”, in which pre-shaped balls 25 composed of solder material are applied to the electrically conductive layer 22. As an alternative to “ball placement”, the solder deposits 25 may, for example, be applied by using stencil printing with a solder paste, followed by a heat-treatment process. The solder deposits 25 may be used as external connection elements to electrically couple the devices 200 to other components, for example a PCB.

The solder material may be formed from metal alloys which are composed, for example, from the following materials: SnPb, SnAg, SnAgCu, SnAgCuNi, SnAu, SnCu and SnBi. Instead of the solder deposits 25, other connecting techniques may be used to electrically couple the encapsulated semiconductor chips 11 and 12 to a PCB, such as for example diffusion soldering or adhesive bonding by using an electrically conductive adhesive.

As illustrated in FIG. 2Q, the semiconductor chips 11 and 12 covered with the layer 15 of polymer material are released from the carrier 10, and the adhesive tape 18 is pealed from the semiconductor chips 11 and 12 as well as from the layer 15 of polymer material. The adhesive tape 18 may feature thermo-release properties, which allow the removal of the adhesive tape 18 during a heat-treatment. The removal of the adhesive tape 18 from the carrier 10 is carried out at an appropriate temperature, which depends on the thermo-release properties of the adhesive tape 18 and is usually higher than 150° C. The carrier 10 may be removed at an earlier stage, for example after the lamination of the polymer material 15 (see FIG. 2F) or the grinding (see FIG. 2G) or any other intermediate process. In a further embodiment, the carrier 10 is not removed, but is part of the devices 200 after singulation.

After the release of the carrier 10 and the adhesive tape 18 the bottom main surfaces of the semiconductor chips 11 and 12 as well as the bottom surface of the layer 15 of polymer material form a common planar surface. This bare backside may be used to dissipate the heat generated by the semiconductor chips 11 and 12 during operation of the devices 200. For example, a heat sink or cooling element may be attached to the backside. Furthermore, the backside may be coated with a protective layer, for example by printing.

As illustrated in FIG. 2R, the devices 200 are separated from one another by separation of the polymer material 15 and the redistribution layers, for example by sawing or a laser beam.

The devices 200 manufactured by the method described above are fan-out type packages. The layer 15 of polymer material allows the redistribution layer to extend beyond the outline of the semiconductor chips 11 and 12. The external connection elements 25 therefore do not need to be arranged within the outline of the semiconductor chips 11 and 12 but can be distributed over a larger area. The increased area which is available for arrangement of the external connection elements 25 as a result of the layer 15 of polymer material means that the external connection elements 25 can not only be arranged at a great distance from one another, but that the maximum number of external connection elements 25 which can be arranged there is likewise increased compared to the situation when all the external connection elements 25 are arranged within the outline of the semiconductor chips 11 and 12.

It is obvious to a person skilled in the art that the devices 200 illustrated in FIG. 2R and the manufacturing thereof as described above are only intended to be an exemplary embodiment, and many variations are possible. For example, semiconductor chips or passives of different types may be included in the same device 200. The semiconductor chips and passives may differ in function, size, manufacturing technology etc.

Furthermore, instead of a prepreg foil or sheet other polymer materials may be used to build the layer 15. Prepreg foils or sheets are especially advantageous in the case the carrier 10 has a large diameter or side length, for example 300 mm. In the case of a carrier 10 having a diameter or side length of 200 mm or less, the semiconductor chips 11 and 12 may also be encapsulated by molding using a duroplastic or thermosetting mold material thereby forming the layer 15. The mold material 15 may be based on an epoxy material and may contain a filling material consisting of small particles of glass (SiO₂) or other electrically insulating mineral filler materials like Al₂O₃ or organic filler materials.

Instead of using a standard PCB industry semi-additive process flow, the redistribution layer may also be manufactured by employing thin film technologies. A device 300 the redistribution layer of which is produced by thin-film technology is schematically illustrated in FIG. 3 in cross section.

In the embodiment illustrated in FIG. 3, the redistribution layer includes two dielectric layers 26 and 27 as well as an electrically conductive layer 28 in the form of a wiring layer. The dielectric layer 26 is deposited on the essentially planar surface formed by the polymer material 15 and the contact elements 13 after grinding. The wiring layer 28 is applied to the dielectric layer 26, with electrical contacts being produced between the contact elements 13 and the wiring layer 28. The dielectric layer 26 has openings in order to produce these contacts.

The dielectric layer 27 is applied to the dielectric layer 26 and the wiring layer 28. The dielectric layer 27 has openings in order to allow an electrical contact between the wiring layer 28 and the external connection elements 25 to be made. Instead of a single wiring layer, it is also possible to use two or more wiring layers if required.

The dielectric layers 26 and 27 may be fabricated in various ways. For example, the dielectric layers 26 and 27 can be deposited from a gas phase, such as sputtering. Each of the dielectric layers 26 and 27 may be up to 10 μm thick. In order to make electrical contacts with the wiring layer 28, the dielectric layers 26 and 27 may be opened by using photolithographic methods and/or etching methods. The wiring layer 28 may, for example, be fabricated by using metallization followed by structuring of the metallization layer in order to form the conductor tracks of the wiring layer 28.

Another technique that may be employed to generated the wiring layer 28 is laser direct structuring. In case of laser direct structuring an electrically insulating polymer foil is placed onto the essentially planar surface formed after grinding. The circuit definition is done by using a laser beam, which activates special additives in the polymer foil in order to allow subsequent selective plating.

In addition, while a particular feature or aspect of an embodiment of the invention may have been disclosed with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used in either the detailed description or the claims, such terms are intended to be inclusive in a manner similar to the term “comprise”. The terms “coupled” and “connected”, along with derivatives may have been used. It should be understood that these terms may have been used to indicate that two elements co-operate or interact with each other regardless whether they are in direct physical or electrical contact, or they are not in direct contact with each other. Furthermore, it should be understood that embodiments of the invention may be implemented in discrete circuits, partially integrated circuits or fully integrated circuits or programming means. Also, the term “exemplary” is merely meant as an example, rather than the best or optimal. It is also to be appreciated that features and/or elements depicted herein are illustrated with particular dimensions relative to one another for purposes of simplicity and ease of understanding, and that actual dimensions may differ substantially from that illustrated herein.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method, comprising:
providing a carrier;
placing a plurality of semiconductor chips over the carrier, the semiconductor chips comprising contact elements;
applying a polymer material over the semiconductor chips and the carrier; and
removing the polymer material until the contact elements are exposed.

2. The method of claim 1, comprising removing the carrier from the semiconductor chips.

3. The method of claim 1, comprising separating the semiconductor chips from each other after the application of the polymer material.

4. The method of claim 1, comprising removing the polymer material mechanically.

5. The method of claim 1, comprising removing the polymer material by grinding.

6. The method of claim 1, comprising applying an electrically conductive layer over the polymer material and the exposed contact elements.

7. The method of claim 6, comprising applying external connection elements to the electrically conductive layer.

8. The method of claim 1, comprising wherein the contact elements protrude by at least 1 μm from the surfaces of the semiconductor chips.

9. The method of claim 1, comprising generating the contact elements by stud bumping.

10. The method of claim 1, comprising generating the contact elements by depositing electrically conductive material from a solution.

11. The method of claim 1, comprising wherein the polymer material has the form of a foil or sheet which is laminated on the semiconductor chips and the carrier.

12. The method of claim 1, comprising wherein the polymer material is a prepreg.

13. The method of claim 1, comprising wherein the polymer material is a bi-stage material.

14. The method of claim 1, comprising wherein after its application the polymer material has an substantially planar surface facing away from the semiconductor chips and the carrier.

15. The method of claim 1, wherein the semiconductor chips have active main surfaces which face away from the carrier after placing the semiconductor chips over the carrier.

16. A device, comprising:
a semiconductor chip comprising contact elements protruding from a first surface of the semiconductor chip;
a polymer material covering the first surface and at least one side surface of the semiconductor chip; and
external connection elements placed over the polymer material covering the first surface of the semiconductor chip, wherein the external connection elements are electrically coupled to the contact elements.

17. The device of claim 16, comprising wherein the contact elements protrude by at least 1 μm from the first surface of the semiconductor chip.

18. The device of claim 16, comprising wherein the polymer material is a prepreg.

19. The device of claim 16, comprising wherein the polymer material is a mold material.

20. The device of claim 16, comprising wherein a second surface of the semiconductor chip opposite to the first surface is exposed from the polymer material.

21. The device of claim 16, wherein an electrically conductive layer is applied over the polymer material and the electrically conductive layer electrically couples the contact elements to the external connection elements.

22. The device of claim 16, comprising wherein at least one of the external connection elements is placed outside the outline of the semiconductor chip.

23. The device of claim 16, comprising wherein the external connection elements are solder balls.

24. A method, comprising:
providing a carrier;
providing a plurality of semiconductor chips, the semiconductor chips comprising contact elements protruding from first surfaces of the semiconductor chips;
placing the semiconductor chips over the carrier with the first surfaces of the semiconductor chips facing away from the carrier;
laminating a prepreg over the semiconductor chips and the carrier;
removing the prepreg until the contact elements are exposed; and
removing the carrier from the semiconductor chips.

25. A method, comprising:
providing a carrier;
providing a plurality of semiconductor chips, the semiconductor chips comprising contact elements protruding from first surfaces of the semiconductor chips by at least 1 μm;
placing the semiconductor chips over the carrier with the first surfaces of the semiconductor chips facing away from the carrier;
applying a prepreg over the semiconductor chips and the carrier;
grinding the prepreg until the contact elements are exposed; and
applying a redistribution layer over the prepreg.
